(19) United States
(12) Patent Application Publication
(10) Pub. No.: US 2010/0072472 A1
(43) Pub. Date: Mar. 25, 2010

(54) Nanostructures With 0, 1, 2, and 3 Dimensions, With Negative Differential Resistance and Method for Making These Nanostructures

(76) Inventors: Patrick Soukiassian, Saint Remy Les Chevreuse (FR); Mathieu Studio Silly, Bures Sur Yvette (FR); Fabrice Charra, Marcoussis (FR)

Correspondence Address: Nixon Peabody LLP, P.O. Box 60610, Palo Alto, CA, 94306, US

(21) Appl. No.: 11/922,970

(22) PCT Filed: Jun. 29, 2006
(86) PCT No.: PCT/EP2006/063692

§ 371 Date: Dec. 27, 2007

(30) Foreign Application Priority Data
Jun. 30, 2005 (FR) 05 51848
Jan. 16, 2006 (FR) 06 50145

(51) Int. Cl. H01L 29/86; H01L 21/04

(52) U.S. Cl. 257/44; 438/584; 977/774; 257/46; 257/E29.325; 257/E21.054

(57) ABSTRACT

Nanostructures with 0, 1, 2 and 3 dimensions, with negative differential resistance and method for making these nanostructures. A nanostructure according to the invention may notably be used in nanoelectronics. It comprises at least one structure (32) or at least one plurality of said at least one structure, at the surface of a silicon carbide substrate (30), the structure being selected from quantum dots, atomic segments, atomic lines and clusters, and at least one metal deposit (34), this metal deposit covering at least the structure or at least the plurality of said at least one structure, or of the combination of two or more of these nanostructures with 0, 1, 2 or 3 dimensions.

### TECHNICAL FIELD

The present invention relates to nanostructures with negative differential resistance (NDR) and to a method for making these nanostructures.

The invention notably applies to the field of nanoelectronics. In particular it allows structures behaving like one-dimensional Esaki diodes, to be obtained at an atomic scale.

### STATE OF THE PRIOR ART

Conventional tunnel diodes, or Esaki diodes, generally consist of a semiconducting material of type p, depleted in electrons, and of a semiconducting material of type n, enriched in electrons. A space-charge region called SCR occurs at the junction between both of these materials.

In order to obtain a tunnel effect, it is recognized that the following conditions have to be met : (a) the Fermi level should be located in the valency band on the p side and in the conduction band on the n side, (b) the thickness of the SCR should be sufficiently small so that the crossing probability by the tunnel effect is sufficient, and (c) at the same energy, electrons and holes must be available in the conduction band and in the valency band, respectively.

Esaki diodes thus have negative differential resistance or NDR: over a certain range of the I (V) characteristic, a current-reducing effect is observed thereon upon increasing the voltage.

A tunnel diode may be prepared by forming a heterostructure with two layers, for example from semiconducting compounds III-V. These compounds may be for example selected from GaAs, GaP, GaN and GaAlAs.

On the topic of tunnel diodes, reference may be made to the following document:
[1] Leo Esaki, Physical Review 109, 603 (1958).

Moreover, reference will be made to the following document:
[2] Lyo and Avouris, Science 245, 1369 (1989).

This document [2] discloses structures consisting of sites which are localized on a particular surface. These sites are formed by means of the tip of a tunnel effect microscope and they have an NDR. The particular surface used is prepared by exposing a (111) surface of silicon to decaborane, at a temperature above 500° C. This surface is then treated by heat annealing.

The authors of the document [2] report the presence of dots for which the density of electron states is larger for the regions covered with a boron atom. These regions have an NDR.

Reference will also be made to the following document:
[3] US 2004 132,242 “Method for the production of one-dimensional nanostructures and nanostructures obtained according to said method”, corresponding to FR 2 823 739.

This document discloses a method for making planar one-dimensional nanostructures. They are obtained by forming parallel atomic lines at the surface of a silicon carbide substrate, and then by deposition and selective absorption of a material between these atomic lines, but not on these lines.

Depending on the material used, the thereby obtained bands may be passivated with NO, NH₃ or sulfur, or may be made electrically conducting with a metal such as potassium.

This document also relates to one-dimensional nanostructures. However, it does not disclose a method for obtaining structures which behave like Esaki diodes at an atomic scale.

### DISCUSSION OF THE INVENTION

The present invention relates to nanostructures with negative differential resistance which are of significant interest in nanoelectronics, as well as to a method for making these nanostructures.

The authors of the present invention discovered surprisingly that nanostructures having a negative differential resistance may be obtained by forming certain structures, notably quantum dots also called nanocrystals, or parallel atomic lines, at the surface of a silicon carbide substrate and by depositing a metal on this surface until the metal covers at least said structures.

With the invention, it is thus possible to make structures which behave like point-like or one-dimensional Esaki diodes at an atomic scale.

Specifically, the object of the present invention is a nanostructure having negative differential resistance, this nanostructure being characterized in that it comprises:

at least one structure or at least one plurality of said at least one structure, at the surface of a silicon carbide substrate, the structure being selected from quantum dots (0 dimension), atomic segments (1 dimension), atomic lines (1 dimension) and clusters (2 or 3 dimensions), and

at least one metal deposit, this metal deposit covering at least the structure or at least the plurality of said at least one structure, or of the combination of two or more of these structures.

In particular, each structure may be quantum dot or an atomic line.

By [symbol] quantum dot [symbol] , the inventors mean a grouping of one to fifty atoms. These are notably isolated atoms, such as silicon or silver atoms or dimers on an SiC surface.

By [symbol] atomic segment [symbol] , the inventors mean a short atomic line, including from one to four atoms in width and about a hundred atoms in length.

By [symbol] cluster [symbol] , the inventors mean a grouping of more than fifty atoms (in 2 or 3 dimensions) such as silicon or silver atoms or dimers on an SiC surface.

Preferably, the metal deposit has a thickness from one to five atomic monolayers.

According to a particular embodiment of the invention, the structure(s) consist(s) of silicon.

According to another particular embodiment, the structure(s) consist(s) of carbon.

Preferably, the silicon carbide (SiC) has a cubic structure.

According to a preferred embodiment of the invention, the surface is a (100) surface of the cubic silicon carbide substrate.

The metal is preferably selected from metals for which the d band is full (for example Ag, Au, Cu), alkaline metals, transition metals, alkaline earth metals and rare earths.

According to a preferred embodiment of the invention, the metal is silver.

The present invention further relates to a method for making a nanostructure with negative differential resistance, this method being characterized in that it comprises the following steps:

at least one structure or at least one plurality of said at least one structure, are formed at the surface of a silicon carbide substrate, the structure being selected from quantum dots, atomic segments, atomic lines and clusters, and

a metal is deposited on said surface, until this metal covers at least the structure or at least the plurality of said at least one structure, or of the combination of two or more of these structures.

In particular, each structure may be a quantum dot or an atomic line.

Preferably, the thickness of the deposited metal represents one to five atomic monolayers of this metal.

According to a particular embodiment of the method, object of the invention, the structure(s) consist(s) of silicon.

According to another particular embodiment, the structure(s) consist of carbon.

Preferably, the silicon carbide has a cubic (polytype 3C (or β)) structure.

According to a preferred embodiment of the invention, the surface is a (100) surface of the cubic silicon carbide substrate.

The density of the structures, such as quantum dots or atomic lines, may be controlled and adjusted so as to make isolated structures, for example ranging from an isolated quantum dot or from an isolated atomic line to a super-lattice of structures distributed in various ways over the surface, for example overwhelmingly parallel atomic lines, according to the needs and according to a method known from the following document:
[4] FR 2 757 183 A—see also the article of Soukiassian et al., Physical Review Letters 79, 2498, 1997.

More particularly, in the case of quantum dots, control and adjustment of the density at the surface are achieved by self-organization, by means of the annealing temperature and time, the displacement of the quantum dots being performed depending on the crystalline arrangement present.

This is a displacement along the atomic lines defined by the substrate, notably when using a β-SiC (100) 4×2 surface.

Typically, in order to obtain quantum dots of silicon, i.e. dimers, on a surface of a β-SiC substrate, the surface of this substrate must be raised to a temperature above 800° C. The silicon atomic lines formed beforehand begin to decompose, [symbol] dimer by dimer [symbol] while leaving segments and then lines of Si vacancies, as well as Si dimers which form quantum dots.

The higher the temperature, the faster is the phenomenon. Thus it is desirable to work between 800° C. and 1,200° C. with this type of compound, and in all cases at a temperature below the temperature for destroying the surface. On this topic, reference will be made to the following document:
[5] (Aristov et al., Surface Science 440 (1999), L825-L830.

The quantum dots may also be displaced by modulating the temperature.

The deposited metal is preferably selected from metals for which the d band is full, alkaline metals such as lithium or rubidium, transition metals such as platinum or palladium, alkaline earth metals and rare earths.

Advantageously, it is selected from silver, gold, copper, indium, gallium, tin, lead, tungsten, molybdenum, niobium and aluminium. Preferentially this metal is silver.

As seen, the thickness of the metal deposit is preferably a few atomic monolayers. In particular, it preferably represents two to three monolayers for silver, and one to two monolayers for a metal, such as for example cesium, the atoms of which have a large radius.

One-dimensional nanostructures having NDR according to the invention, are of great interest in the field of very fast switching and in the field of oscillators and devices at an atomic scale which operate at very high frequencies. The obtained structures are thus real active components, which is without precedent.

### DESCRIPTION OF THE DRAWINGS

The present invention will be better understood upon reading the description of exemplary embodiments given hereafter, purely as an indication and by no means as a limitation, with reference to the appended drawings wherein:

FIG. 1 illustrates an STS curve, or a scanning tunnel spectroscopy curve, wherein the intensity I expressed in nA is plotted versus the voltage V expressed in mV, for conditions controlling electron emission so that the set (control) points for the current are not very different from 10 nA and the set (control) point of the voltage is not very different from 4.9 V,

FIG. 2 is an enlargement of the I area of the curve of FIG. 1,

FIGS. 3-5 are schematic sectional views of exemplary nanostructures according to the invention,

FIG. 6 is an STM image of an SiC surface including Si lines and quantum dots which are covered with silver and have negative differential resistance Rd,

FIG. 7 is a schematic view of a surface bearing quantum dots which are formed according to the present invention,

FIG. 8 is a schematic view of a surface on which quantum dots have been formed and organized according to the invention,

FIG. 9 is a schematic sectional view of a substrate, the surface of which bears a quantum dot covered with metal according to the invention,

FIG. 10 is a schematic sectional view of a substrate, the surface of which bears several quantum dots which are organized and covered with metal according to the invention, and

FIG. 11 is a schematic top view of the surface of a substrate bearing quantum dots on which metal is deposited through a mask.

### DETAILED DISCUSSION OF PARTICULAR EMBODIMENTS

An example for making a nanostructure according to the invention is given hereafter, purely as an indication and by no means as a limitation.

One begins by preparing a β-SiC (100) surface provided with atomic lines.

More specifically, in the relevant example, a β-SiC(100) surface covered with atomic lines of Si which lie on a reconstructed c(4×2) surface, is prepared.

For the general preparation of atomic lines, reference will be made to the following document:
[6] U.S. Pat. No. 6,274,234, “Very long and highly stable atomic wires, method for making these wires, application in nanoelectronics”, corresponding to WO 98/27578.

The procedure followed in the example is given hereafter.

a) A cubic silicon carbide (3C—SiC) sample is placed in an enclosure, in which prevails a pressure below 5×10⁻⁹ Pa, and the sample is heated by having a current directly pass into this sample, for several hours at 650° C., and then several times at 1,100° C. for one minute.

b) By means of a silicon source heated to 1,300° C., several silicon monolayers are deposited on the surface (100) of the cubic SiC.

c) By thermal annealings, a portion of the deposited silicon is evaporated in a controlled way until the surface has an organization (reconstruction) of symmetry 3×2 at an atomic scale. This symmetry of the surface may be checked by electron diffraction.

This 3×2 surface consists of extremely dense silicon atomic lines, lying on a surface entirely consisting of silicon atoms. With new annealings, the density of these lines may be reduced in a controlled way and for example densities of 3×2, 5×2 or even 8×2 may be achieved for example.

On the thereby obtained surface, silver is then deposited. The procedure is as indicated hereafter.

In a first step, a silver source is prepared and calibrated. To do this, a source of silver atoms is placed in an ultra-vacuum chamber and degassed carefully. The source is considered to be sufficiently degassed when the increase in pressure in the chamber, during the time required for evaporating a silver monolayer, does not exceed 2×10⁻⁹ Pa.

The next step consists of depositing silver atoms on the surface obtained previously.

The procedure to be followed is given hereafter.

The SiC surface including atomic lines of silicon is then introduced into the ultra-vacuum chamber and is placed at about 3 cm from the silver source. The source is then heated by suitable means such as by the Joule effect. Silver atoms then evaporate from the source and are deposited on the SiC surface.

The thickness of the silver deposit is checked by means of quartz scales. The XPS signal from a core level of silver may also be tracked.

The silver atoms are deposited so as to cover the silicon atom lines. The amount of silver to be deposited corresponds to about three atomic monolayers.

In order to exert more accurate control on the deposit, it is possible to use one or more masks, as this is usually done in the field of electronics. This(ese) mask(s) may for example consist of SiO₂.

In the considered example, silver is deposited so that it entirely covers the silicon atoms of the surface as well as the lines formed on this surface. In this case, the formed surface has a reconstruction of the c-4×2 type.

The obtained nanostructure has an NDR. To demonstrate this NDR, the response of the surface obtained by STS, i.e. by scanning tunneling spectroscopy, is investigated. The atomic lines of Si, which are covered with silver, provide a response I(V) which exhibits negative differential resistance. This is not the case of the surface which is also covered with silver (2×3) but located between the lines.

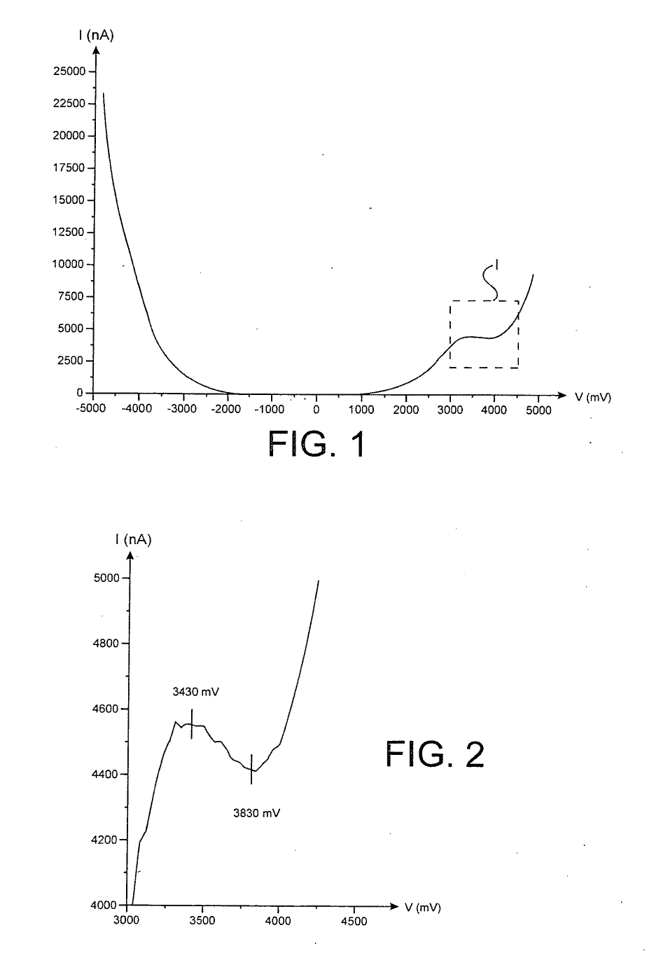

In FIG. 1, the I(V) spectroscopy curve in absolute values at a linear scale may be seen for covered atomic lines. The NDR is better demonstrated in FIG. 2 which is an enlargement of the portion I of FIG. 1, delimited by dotted lines.

A super-lattice of overwhelmingly parallel atomic lines which have negative differential resistance, has therefore been made. These atomic lines behave as one-dimensional [symbol] Esaki diodes [symbol] at an atomic scale.

It is specified that the curve I(V) of FIG. 1 illustrates the changes in the intensity I of the current which passes between the tip of the microscope used and the investigated sample by the tunnel effect, depending on the voltage V between the tip and the sample.

The tip of the microscope was able to scan the sample and the typical response appears at each crossing of an atomic line.

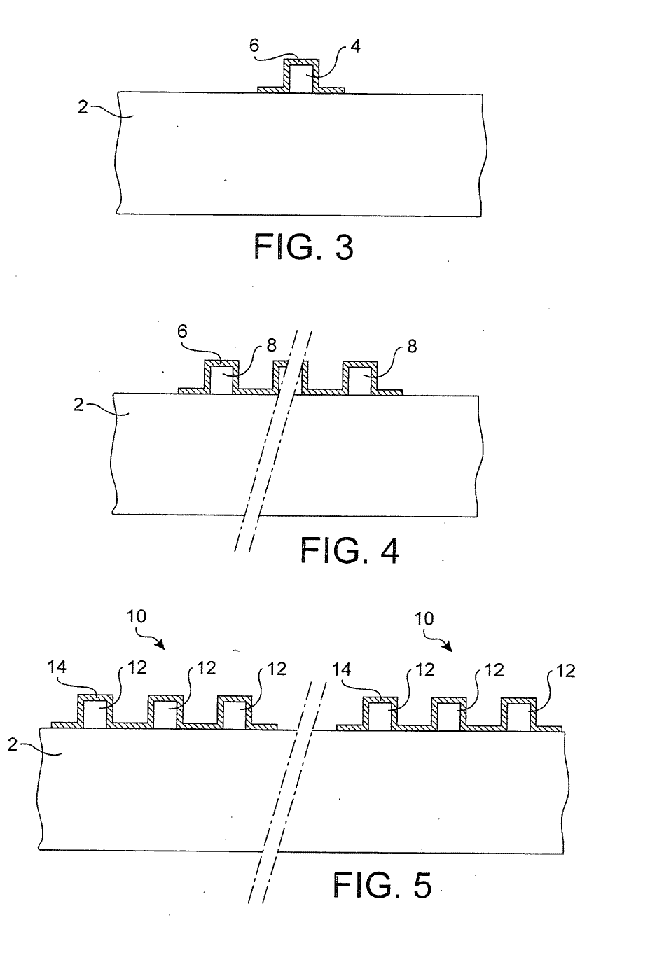

FIGS. 3-5 are schematic sectional views of exemplary NDR nanostructures according to the invention, formed on a (100) surface of a substrate 2 in silicon carbide with a cubic structure.

The nanostructure of FIG. 3 comprises a single atomic line 4 of silicon on the surface of the substrate 2. This line 4 is covered with a silver layer 6, the thickness of which represents a few silver monolayers, preferably three monolayers.

The nanostructure of FIG. 4 comprises several parallel atomic lines of silicon 8, formed on the (100) surface of the substrate 2. In this example, the curve 6 covers each line 8 as well as the portions of the (100) surface which are comprised between these lines.

The nanostructure of FIG. 5 comprises several sets 10 of silicon atomic lines which are parallel to each other. These sets are spaced apart from each other. Further, in each set, a silver layer 14, the thickness of which represents a few atomic layers of silver, covers the atomic lines of this set as well as the portions of the (100) surface, which are comprised between these lines.

In the examples of FIGS. 3-5, masks (not shown) may be used for depositing the silver layers at the desired locations.

Another example for making nanostructures according to the invention is given hereafter, purely as an indication and by no means as a limitation.

A β-SiC(100) surface is again prepared, covered with Si atomic lines which lie on a c(4×2) reconstructed surface, and steps a) and b), which have been discussed earlier, and then the following step are accomplished:

c1) By heat annealings typically carried out between 800° C. and 1,200° C., a portion of the deposited silicon is evaporated in a controlled way until the surface has the following nanostructures: isolated quantum dots (silicon dimers), segments of silicon atoms or even clusters of silicon. This organization of the surface may be checked by electron diffraction. On the thereby obtained surface, silver is then deposited in a small amount. In the present case, silver is advantageously deposited on isolated quantum dots; but it may also be deposited on the surface surrounding the dots.

For this deposition, one proceeds as indicated above (first step and next step).

The SiC surface including the nanostructures as defined above, is then introduced into the ultra-vacuum chamber and placed at about 3 cm from the silver source. The source is heated by suitable means, such as by the Joule effect. Silver atoms then evaporate from the source and are deposited on the SiC surface.

The thickness of the silver deposit is ckecked by means of quartz scales. The signal XPS from a core level of silver may also be tracked.

The silver atoms are deposited so as to cover the silicon nanostructures. The amount of silver to be deposited corresponds to about three atomic monolayers. In order to exert more accurate control on the deposit, it is further possible to use the mask(s), which has(have) been mentioned above.

In the relevant example, silver is deposited so that it entirely covers the silicon nanostructures. In this case, the formed surface has a reconstruction of type c-2×4.

The new obtained nanostructures have an NDR. To demonstrate this NDR, the response of the surface, as obtained by STS, i.e. by scanning tunneling spectroscopy, is investigated. The Si nanostructures, which are covered with silver, give a response I(V) which exhibits negative differential resistance. This is not the case of the surface which is also covered with silver (2×3) but located between the nanostructures.

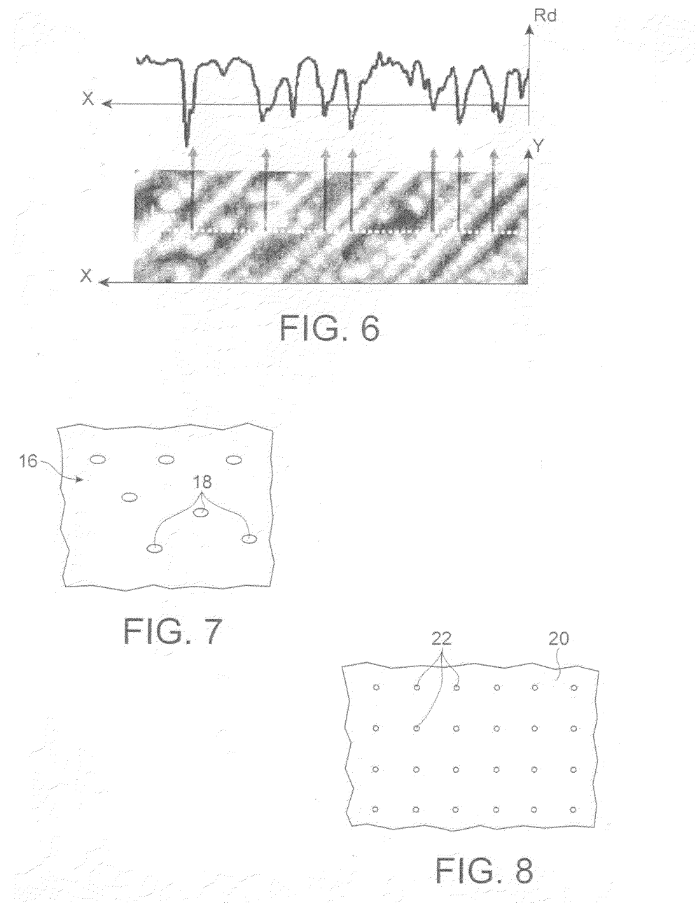

In FIG. 6, the image obtained by STM, i.e. scanning tunneling microscopy, in a topographic mode, of a SiC surface including Si quantum dots and lines, may be seen, which are covered with silver and have negative differential resistance Rd.

The latter is measured by scanning tunnel spectroscopy (STS) and it is negative when one passes vertically above a dot or an atomic line which are covered with silver. This may be seen in FIG. 6, where the variations of Rd are illustrated along a line parallel to an X axis, the Y axis of FIG. 6 being perpendicular to X.

A set of nanostructures which have negative differential resistance, has therefore been made. These nanostructures behave as low dimensionality [symbol] Esaki diodes [symbol] such as one-dimensional diodes at an atomic scale.

It is specified that the tip of the tunnel effect microscope was capable of scanning the sample and that the typical response appears at each crossing of a nanostructure.

FIG. 7 is a schematic view of the surface 16 of an SiC substrate, on which quantum dots 18 in silicon were formed according to the invention.

FIG. 8 is a schematic view of the surface 20 of an SiC substrate, on which quantum dots 22 in silicon were formed, according to the invention, and then organized.

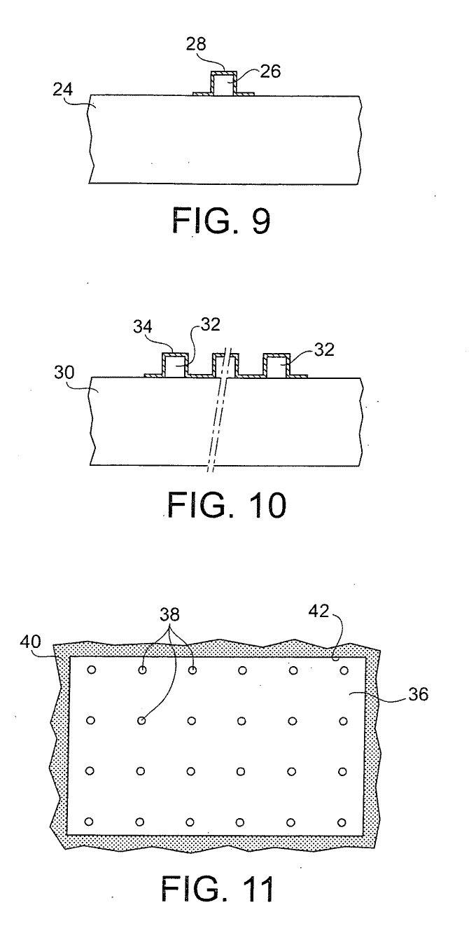

FIG. 9 is a schematic sectional view of an SiC substrate 24, the surface of which bears a quantum dot 26 in silicon, which was formed and then covered with a metal 28 such as silver, according to the invention.

FIG. 10 is a schematic sectional view of an SiC substrate 30, the surface of which bears several quantum dots 32 in silicon, which were formed according to the invention and then organized and subsequently covered with a metal 34 such as silver, according to the invention. In the example of FIG. 10, the space between the dots was also covered with metal.

According to the invention, it is possible to use one or more masks for depositing the metal layers, here silver layers, at the desired locations.

This is schematically illustrated in FIG. 11. The surface 36 of an SiC substrate is shown therein, on which quantum dots 38 in silicon were formed according to the invention, and then these dots were organized.

A mask 40 for example in silicon may then be placed on the surface and silver may be deposited on the dots through the mask. In the example of FIG. 11, this mask includes an aperture 42 letting through the silver atoms so that they are deposited on the surface.

However, a more complex mask, including several apertures, or even several masks, may also be used for depositing silver in various areas of the surface, spaced apart from each other.

Let us specify that the nanostructures according to the invention behave like Esaki diodes in the sense that like the latter, they have NDR.

Let us also note that these nanostructures are metal-semiconductor junctions.

Let us also mention that a further benefit from the present invention lies in the fact that the surfaces bearing the nanostructures covered with a metal according to the invention, may also be used as a device for storing information, because the nanostructures are easily locatable by reading with a scanning tunneling near-field microscope.

Indeed, let us note that the topography of the surface, on which the nanostructures are formed, becomes a real map and the nanostructures may be more or less spaced apart. Information may therefore be stored between these nanostructures or in areas containing these nanostructures, and defined spaces may be relocated since each area is locatable, so that they may be counted and the sought-after space may thus be attained.

Moreover, the areas may be specially identified, for example, by the number of nanostructures or by the layout of the latter.

In the present invention, instead of silicon nanostructures (covered with metal), carbon nanostructures (covered with metal) may be formed and used.

In the case of a substrate of silicon carbide with a cubic structure, instead of a (100) surface of such a substrate, other surfaces may be used, for example (111), (110) surfaces etc.

Further, instead of a cubic structure for the silicon carbide substrate, other structures may be used, for example a hexagonal structure or a rhombohedral structure.

1. A nanostructure having negative differential resistance, this nanostructure being characterized in that it comprises:
at least one structure or at least one plurality of said at least one structure, at the surface of a silicon carbide substrate, the structure being selected from quantum dots, atomic segments, atomic lines and clusters, and
at least one metal deposit, this metal deposit covering at least the structure or at least the plurality of said at least one structure, or of the combination of two or more of these structures.

2. The nanostructure according to claim 1, wherein each structure is a quantum dot.

3. The nanostructure according to claim 1, wherein each structure is an atomic line.

4. The nanostructure according to claim 1, wherein each structure is an atomic segment.

5. The nanostructure according to claim 1, wherein the metal deposit has a thickness ranging from one to five atomic monolayers.

6. The nanostructure according to claim 1, wherein the structure(s) consist(s) of silicon.

7. The nanostructure according to claim 1, wherein the structure(s) consist(s) of carbon.

8. The nanostructure according to claim 1, wherein the silicon carbide has a cubic structure.

9. The nanostructure according to claim 8, wherein the surface is a surface of the cubic silicon carbide substrate.

10. The nanostructure according to claim 1, wherein the metal is selected from metals, for which the d band is full, alkaline metals, transition metals, alkaline earth metals and rare earths.

11. The nanostructure according to claim 10, wherein the metal is silver.

12. A method for making a nanostructure having negative differential resistance, this method being characterized in that it comprises the following steps:
at least one structure or at least one plurality of said at least one structure, are formed at the surface of a silicon carbide substrate, the structure being selected from quantum dots, atomic segments, atomic lines and clusters, and
a metal is deposited on said surface, until this metal covers at least the structure or at least the plurality of said at least one structure, or of the combination of two or more of these structures.

13. The method according to claim 12, wherein each structure is a quantum dot.

14. The method according to claim 12, wherein each structure is an atomic line.

15. The method according to claim 12, wherein each structure is an atomic segment.

16. The method according to claim 12, wherein the thickness of the deposited metal represents one to five atomic monolayers of this metal.

17. The method according to claim 12, wherein the structure(s) consist(s) of silicon.

18. The method according to claim 12, wherein the structure(s) consist(s) of carbon.

19. The method according to claim 12, wherein the silicon carbide has a cubic structure.

20. The method according to claim 19, wherein the surface is a surface of the cubic silicon carbide substrate.

21. The method according to claim 12, wherein the metal is selected from metals for which the d band is full, alkaline metals, transition metals, alkaline earth metals, and rare earths.

22. The method according to claim 21, wherein the metal is silver.
